(19) United States
(12) Patent Application Publication
(10) Pub. No.: US 2011/0018398 A1
(43) Pub. Date: Jan. 27, 2011

(54) PIEZOELECTRIC VIBRATOR, MANUFACTURING METHOD OF PIEZOELECTRIC VIBRATOR, OSCILLATOR, ELECTRONIC DEVICE, AND RADIO-CONTROLLED CLOCK

(76) Inventor: Junya Fukuda, Chiba-shi (JP)

Correspondence Address: Brinks Hofer Gilson & Lione/Seiko Instruments Inc., P.O. Box 10395, Chicago, IL, 60611, US

(21) Appl. No.: 12/842,623

(22) Filed: Jul. 23, 2010

(30) Foreign Application Priority Data
Jul. 24, 2009 (JP) 2009-173382

(51) Int. Cl. H01L 41/053; H01L 41/22

(52) U.S. Cl. 310/344; 29/25.35

(57) ABSTRACT

Providing a piezoelectric vibrator which is capable of securing the degree of vacuum in a cavity and can be manufactured with high efficiency and to provide a manufacturing method thereof. A piezoelectric vibrator 1 including: a base board 2 and a lid board 3 which are superimposed onto each other so as to form a cavity C therebetween; a piezoelectric vibrating reed 4 which is accommodated in the cavity and bonded to the base board; a gettering material 34 which is formed in the base board to be accommodated in the cavity; a bonding film 35 which is formed on the entire surface of the lid board facing the base board so as to bond both boards to each other at a portion thereof being in contact with the base board, wherein the bonding film is formed of a material which is capable of absorbing surrounding gas by being activated with laser irradiation.

### RELATED APPLICATIONS

This application claims priority under 35 U.S.C. §119 to Japanese Patent Application No. 2009-173382 filed on Jul. 24, 2009, the entire content of which is hereby incorporated by reference.

### BACKGROUND OF THE INVENTION

1. Field of the Invention

The present invention relates to an SMD-type piezoelectric vibrator in which a piezoelectric vibrating reed is sealed in a cavity formed between two bonded boards, a manufacturing method of the piezoelectric vibrator, and an oscillator, an electronic device, and a radio-controlled clock each having the piezoelectric vibrator.

2. Description of the Related Art

Recently, a piezoelectric vibrator using a piezoelectric vibrating reed made of a piezoelectric material such as quartz crystal is used in a cellular phone and a portable information terminal as the time source, the timing source of a control signal, a reference signal source, and the like. As the piezoelectric vibrating reed, a turning-fork type piezoelectric vibrating reed having a pair of vibrating arms is used.

As the piezoelectric vibrator of this type, an SMD (Surface Mount Device)-type piezoelectric vibrator is known.

As shown in FIGS. 17 and 18, as an SMD-type piezoelectric vibrator 200, there is proposed one in which a package 209 is formed by a base board 201 and a lid board 202, and a piezoelectric vibrating reed 203 is accommodated in a cavity C formed inside the package 209. The base board 201 and the lid board 202 are bonded to each other by an anodic bonding using a bonding film 207 which is formed on the base board 201 and disposed between both boards.

Meanwhile, in general piezoelectric vibrators, it is preferable to suppress an equivalent resistance value (effective resistance value Re) to a low value. Since a piezoelectric vibrator having a low equivalent resistance value is capable of vibrating a piezoelectric vibrating reed with a low power, a piezoelectric vibrator having high energy efficiency can be achieved.

As a typical method of suppressing the equivalent resistance value, as shown in FIGS. 17 and 18, there is known a method of creating a near-perfect vacuum in the sealed cavity C of the piezoelectric vibrating reed 203 so as to decrease a series resonance resistance value (R1) which is proportional to the equivalent resistance value. Moreover, as a method of creating a near-perfect vacuum in the cavity C, JP-A-2003-142976 discloses a method (gettering method) of sealing a gettering material 220 made, for example, of aluminum and formed on the base board 201 in the cavity C and activating the gettering material 220 with laser irradiation from the outside. According to this method, since oxygen generated at the time of anodic bonding can be absorbed by the activated gettering material 220, it is possible to create a near-perfect vacuum in the cavity C. Since the gettering material 220 is removed by being evaporated by the laser irradiation at the time of gettering, the gettering material 220 at the same position cannot be repeatedly gettered.

However, in the piezoelectric vibrator of the related art, there is a case where the degree of vacuum in the cavity cannot be increased to satisfy a predetermined requirement even when the entire areas of the gettering material are gettered. A piezoelectric vibrator that does not satisfy such a requirement for the degree of vacuum will become a defective product.

To solve this problem, the formation area of the gettering material on the base board may be increased to increase the number of times the gettering material can be gettered. However, besides the gettering material, the formation areas of other constituent elements such as inner electrodes electrically connected to the piezoelectric vibrating reed must be secured on the base board. Therefore, it is difficult to increase the formation area of the gettering material to an extent that the above-described problem is solved.

### SUMMARY OF THE INVENTION

The present invention has been made in view of the foregoing, and an object of the present invention is to provide a piezoelectric vibrator which is capable of securing the degree of vacuum in a cavity and can be manufactured with high efficiency and to provide a manufacturing method thereof.

The present invention provides the following means in order to solve the problems.

According to an aspect of the present invention, there is provided a piezoelectric vibrator including: a base board and a lid board which are superimposed onto each other so as to form a cavity therebetween; a piezoelectric vibrating reed which is accommodated in the cavity and bonded to the base board; a gettering material which is formed in the base board to be accommodated in the cavity; a bonding film which is formed on the entire surface of the lid board facing the base board so as to bond both boards to each other at a portion thereof being in contact with the base board, wherein the bonding film is formed of a material which is capable of absorbing surrounding gas by being activated with laser irradiation.

According to this aspect, since the bonding film is formed of a material capable of absorbing surrounding gas by being activated with laser irradiation, by activating the portion of the bonding film positioned inside the cavity with laser irradiation, the gas in the cavity can be absorbed and guttered, and thus the degree of vacuum in the cavity can be increased. Accordingly, the gettering can be achieved by irradiating the bonding film as well as the gettering material with a laser beam, and the degree of vacuum in the cavity can be ensured when compared to the case of gettering only the gettering material.

Moreover, such an operational advantage can be obtained without increasing the formation area of the gettering material on the base board. Furthermore, since the bonding film only needs to be formed over the entire surface of the lid board facing the base board, the piezoelectric vibrator can be manufactured more efficiently compared to the case of forming another gettering material used for only gettering in the lid board, for example.

Moreover, the gettering material and the bonding film may each be simultaneously irradiated with a laser beam so that first laser irradiation marks are formed thereon.

In this case, according to the piezoelectric vibrator, since the gettering material and the bonding film are simultaneously irradiated with a laser beam to form the first laser irradiation marks, the gettering effect can be doubled by one laser irradiation instance. Therefore, it is possible to perform the gettering effectively while ensuring the degree of vacuum in the cavity.

Moreover, second laser irradiation marks may be formed at positions of the bonding film in the cavity where they do not overlap with the gettering material as viewed from the normal direction of the base board.

In this case, according to the piezoelectric vibrator, by irradiating only the bonding film with a laser beam to form the second laser irradiation marks, it is possible to getter only the bonding film. For this reason, by performing laser irradiation so as to form the second laser irradiation marks, the degree of vacuum in the cavity can be increased by a smaller amount than the case of performing laser irradiation so as to form the first laser irradiation marks. Therefore, by performing the laser irradiation so as to form the first laser irradiation marks or the second laser irradiation marks based on the degree of vacuum in the cavity, it is possible to finely adjust the extent of increasing the degree of vacuum in the cavity and to thus adjust the degree of vacuum with high precision.

Furthermore, in the piezoelectric vibrator in which the first laser irradiation marks are formed on the entire area of the gettering material, even when the entire area of the gettering material is gettered and after the first laser irradiation marks are formed, by gettering the bonding film to form the second laser irradiation marks, it is possible to increase the degree of vacuum in the cavity further.

Furthermore, the gettering material and the bonding film may be formed of different materials.

In this case, since the gettering material and the bonding film are formed of different materials, by forming the gettering material using a material (e.g., chromium) capable of effectively increasing the degree of vacuum in the cavity by getting and forming the bonding film using a material (e.g., aluminum) capable of tightly bonding the base board and the lid board to each other, it is possible to increase effectively the degree of vacuum in the cavity by gettering while ensuring the sealing state of the cavity with bonding of the bonding film.

Furthermore the gettering material and the bonding film may be formed of different materials which are respectively capable of absorbing different surrounding gases by being activated with laser irradiation.

According to another aspect of the present invention, there is provided a method for manufacturing a piezoelectric vibrator including: a base board and a lid board which are superimposed onto each other so as to form a cavity therebetween; a piezoelectric vibrating reed which is accommodated in the cavity and bonded to the base board; a gettering material which is formed in the base board to be accommodated in the cavity; a bonding film which is formed on the entire surface of the lid board facing the base board so as to bond both boards to each other at a portion thereof being in contact with the base board, wherein the bonding film is formed of a material which is capable of absorbing surrounding gas by being activated with laser irradiation, and wherein the method includes a first gettering step of simultaneously irradiating the gettering material and the bonding film with a laser beam.

According to this aspect, since the gettering material and the bonding film are simultaneously irradiated with a laser beam in the first gettering step, the gettering effect can be doubled by one laser irradiation instance. Therefore, it is possible to perform the gettering effectively while ensuring the degree of vacuum in the cavity.

Moreover, the manufacturing method according to the above aspect of the present invention may include a second gettering step of irradiating portions of the bonding film in the cavity with a laser beam where they do not overlap with the gettering material as viewed from the normal direction of the base board.

In this case, in the second gettering step, since a laser beam is irradiated onto portions of the bonding film in the cavity where they do not overlap with the gettering material as viewed from the normal direction of the base board, only the bonding film is gettered. Therefore, the degree of vacuum in the cavity can be increased by a smaller amount than the first gettering step. Accordingly, by performing the first gettering step or the second gettering step based on the degree of vacuum in the cavity, it is possible to finely adjust the extent of increasing the degree of vacuum in the cavity and to thus adjust the degree of vacuum with high precision.

Moreover, even when the entire areas of the gettering material are irradiated with a laser beam in the first gettering step, by gettering the bonding film in the second gettering step, it is possible to increase the degree of vacuum in the cavity further.

According to a further aspect of the present invention, there is provided an oscillator in which the piezoelectric vibrator according to the above aspect of the present invention is electrically connected to an integrated circuit as an oscillating piece.

According to a still further aspect of the present invention, there is provided an electronic device in which the piezoelectric vibrator according to the above aspect of the present invention is electrically connected to a time counting portion.

According to a still further aspect of the present invention, there is provided a radio-controlled clock in which the piezoelectric vibrator according to the above aspect of the present invention is electrically connected to a filter portion.

In the piezoelectric vibrator according to the above aspect of the present invention, since the degree of vacuum in the cavity can be secured, it is possible to decrease the series resonance resistance value to a suitable value and to thus suppress production of defective products to increase the yield. Therefore, it is possible to reduce the cost of an oscillator, an electronic device, and a radio-controlled clock.

According to the piezoelectric vibrator as in the above aspect of the present invention, it is possible to secure the degree of vacuum in the cavity and manufacture the piezoelectric vibrator with high efficiency.

According to the manufacturing method of the piezoelectric vibrator as in the above aspect of the present invention, it is possible to secure the degree of vacuum in the cavity of the piezoelectric vibrator and manufacture the piezoelectric vibrator with high efficiency.

### BRIEF DESCRIPTION OF THE DRAWINGS

FIG. 1 is a perspective view showing an external appearance of a piezoelectric vibrator according to a first embodiment.

FIG. 2 is a view showing the inner configuration of the piezoelectric vibrator shown in FIG. 1.

FIG. 3 is a sectional view of the piezoelectric vibrator taken along the line A-A in FIG. 2.

FIG. 4 is an exploded perspective view of the piezoelectric vibrator shown in FIG. 1.

FIG. 5 is a planar view of a piezoelectric vibrating reed constituting the piezoelectric vibrator shown in FIG. 1.

FIG. 6 is a bottom view of the piezoelectric vibrating reed shown in FIG. 5.

FIG. 7 is a sectional view taken along the line B-B in FIG. 5.

FIG. 8 is a view showing the inner configuration of the piezoelectric vibrator shown in FIGS. 1 to 4 after gettering is performed.

FIG. 9 is a flowchart of the manufacturing method of the piezoelectric vibrator shown in FIG. 8.

FIG. 10 is an exploded perspective view of a wafer assembly in which a base board wafer and a lid board wafer are anodically bonded to each other in a state where a piezoelectric vibrating reed is accommodated in a cavity.

FIG. 11 is a view showing the inner configuration of a piezoelectric vibrator according to a second embodiment.

FIG. 12 is a flowchart showing the manufacturing method of the piezoelectric vibrator shown in FIG. 11.

FIG. 13 is a view showing the internal configuration of a modified example of the piezoelectric vibrator according to the second embodiment.

FIG. 14 is a view showing the schematic configuration of an oscillator.

FIG. 15 is a block diagram of an electronic device.

FIG. 16 is a block diagram of a radio-controlled clock.

FIG. 17 is a plan view showing a state where a lid board of a piezoelectric vibrator according to the related art is removed.

FIG. 18 is a sectional view taken along the line C-C in FIG. 17.

### DETAILED DESCRIPTION OF THE PREFERRED EMBODIMENTS

### First Embodiment

Hereinafter, a piezoelectric vibrator according to a first embodiment of the present invention will be described with reference to the drawings.

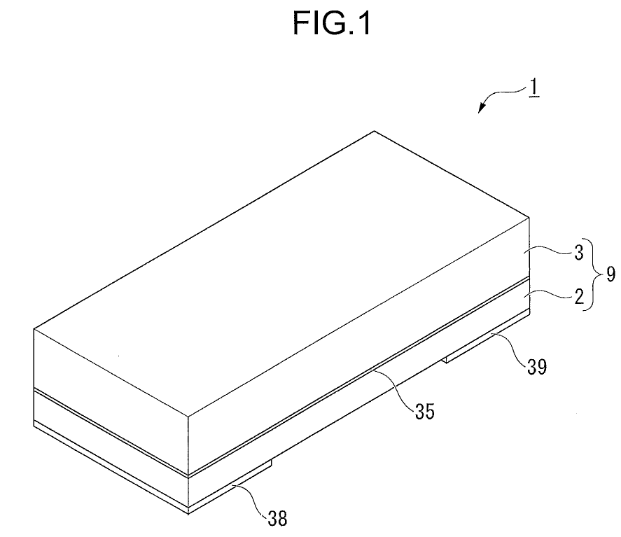

As shown in FIGS. 1 to 4, a piezoelectric vibrator 1 according to the present embodiment is a SMD-type piezoelectric vibrator including: a base board 2 and a lid board 3 which are superimposed onto each other to form a cavity C therebetween; and a piezoelectric vibrating reed 4 which is accommodated in the cavity C and bonded to the base board 2, and is a work in process in the progress of manufacturing a piezoelectric vibrator 70 described later which is a finished product.

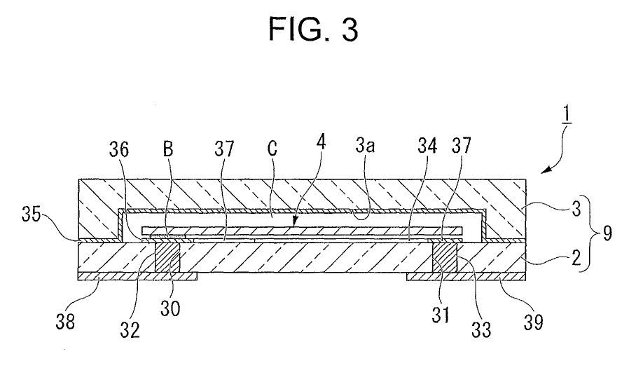

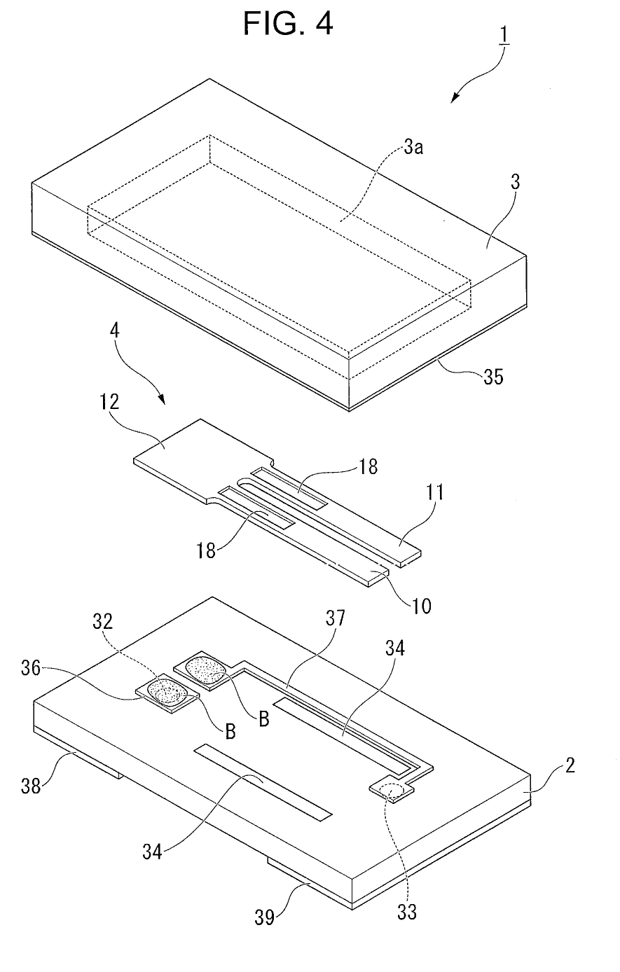

In FIGS. 3 and 4, for better understanding of the drawings, illustrations of piezoelectric vibrating reed 4, excitation electrode 15, extraction electrodes 19 and 20, mount electrodes 16 and 17, and weight metal film 21 are omitted.

### Piezoelectric Vibrating Reed

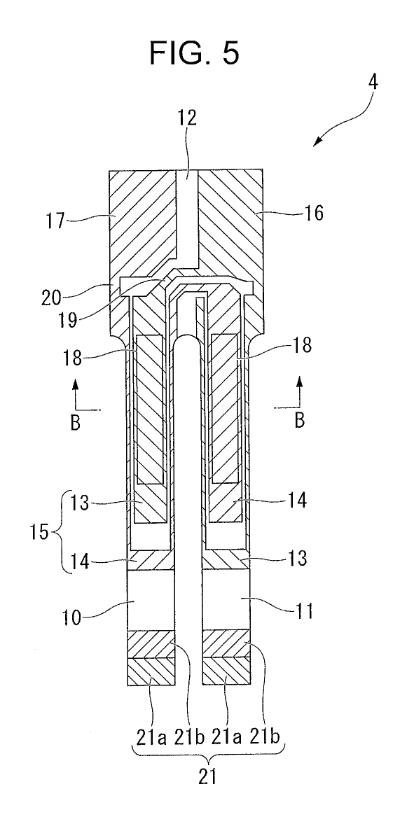

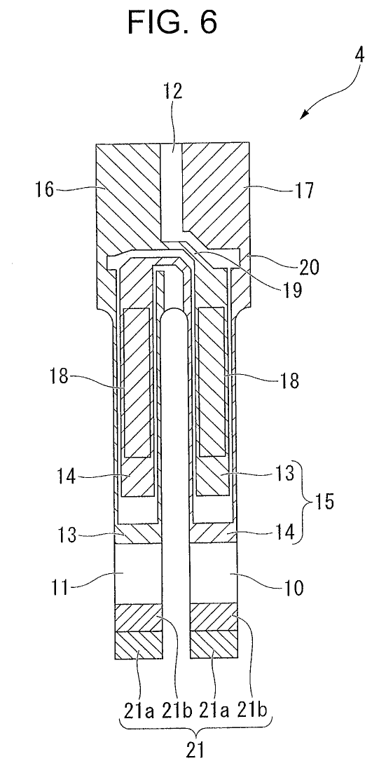

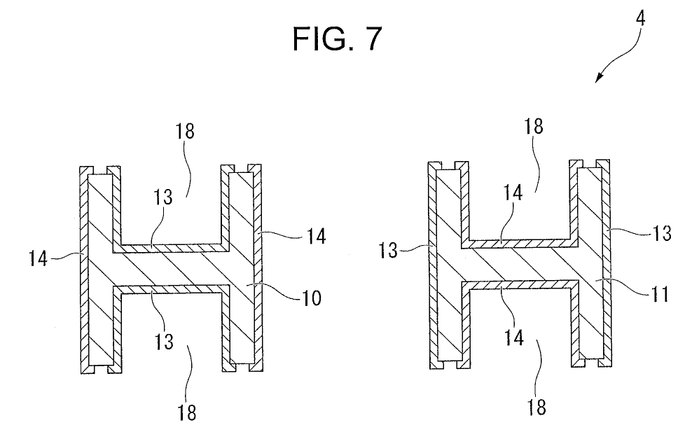

As shown in FIGS. 5 to 7, the piezoelectric vibrating reed 4 is a turning-fork type vibrating reed which is made of a piezoelectric material such as quartz crystal, lithium tantalate, or lithium niobate and is configured to vibrate when a predetermined voltage is applied thereto. The piezoelectric vibrating reed 4 includes: a pair of vibrating arms 10 and 11 disposed in parallel to each other; a base portion 12 to which the base end sides of the pair of vibrating arms 10 and 11 are integrally fixed; an excitation electrode 15 which is formed on the outer surfaces of the base ends of the pair of vibrating arms 10 and 11 so as to allow the pair of vibrating arms 10 and 11 to vibrate and includes a first excitation electrode 13 and a second excitation electrode 14; and mount electrodes 16 and 17 which are electrically connected to the first excitation electrode 13 and the second excitation electrode 14, respectively. The piezoelectric vibrating reed 4 is provided with groove portions 18 which are formed on both principal surfaces of the pair vibrating arms 10 and 11 along the longitudinal direction of the vibrating arms 10 and 11. The groove portions 18 are formed so as to extend from the base end sides of the vibrating arms 10 and 11 up to approximately the middle portions thereof.

The excitation electrode 15 including the first excitation electrode 13 and the second excitation electrode 14 is an electrode that allows the pair of vibrating arms 10 and 11 to vibrate at a predetermined resonance frequency in a direction to move closer to or away from each other and is patterned on the outer surfaces of the pair of vibrating arms 10 and 11 in an electrically isolated state. Specifically, the first excitation electrode 13 is mainly formed on the groove portion 18 of one vibrating arm 10 and both side surfaces of the other vibrating arm 11. On the other hand, the second excitation electrode 14 is mainly formed on both side surfaces of one vibrating arm 10 and the groove portion 18 of the other vibrating arm 11.

Moreover, the first excitation electrode 13 and the second excitation electrode 14 are electrically connected to the mount electrodes 16 and 17 via the extraction electrodes 19 and 20, respectively, on both principal surfaces of the base portion 12. A voltage is applied to the piezoelectric vibrating reed 4 via the mount electrodes 16 and 17. The above-mentioned excitation electrode 15, mount electrodes 16 and 17, and extraction electrodes 19 and 20 are formed by coating of a conductive film of chromium (Cr), nickel (Ni), aluminum (Al), and titanium (Ti), for example.

Furthermore, the tip ends of the pair of the vibrating arms 10 and 11 are coated with a weight metal film 21 for mass adjustment of their own vibration states (tuning the frequency) in a manner such as to vibrate within a predetermined frequency range. The weight metal film 21 is divided into a rough tuning film 21a used for tuning the frequency roughly and a fine tuning film 21b used for tuning the frequency finely. By tuning the frequency with the use of the rough tuning film 21a and the fine tuning film 21b, the frequency of the pair of the vibrating arms 10 and 11 can be set to fall within the range of the nominal (target) frequency of the device.

The piezoelectric vibrating reed 4 configured in this way is mounted on an upper surface of the base board 2 by bump bonding using bumps B made of gold or the like as shown in FIGS. 3 and 4. More specifically, bump bonding is achieved in a state where the pair of mount electrodes 16 and 17 come into contact with two bumps B formed on lead-out electrodes 36 and 37 described later, respectively, which are patterned on the upper surface of the base board 2. In this way, the piezoelectric vibrating reed 4 is supported in a state of being floated from the upper surface of the base board 2, and the mount electrodes 16 and 17 and the lead-out electrodes 36 and 37 are electrically connected to each other.

### Piezoelectric Vibrator

As shown in FIGS. 1 to 4, the piezoelectric vibrator 1 according to the present embodiment includes a package 9 in which the base board 2 and the lid board 3 are laminated in two layers.

The base board 2 is a transparent insulating board made of a glass material, for example, soda-lime glass, and is formed in a board-like form.

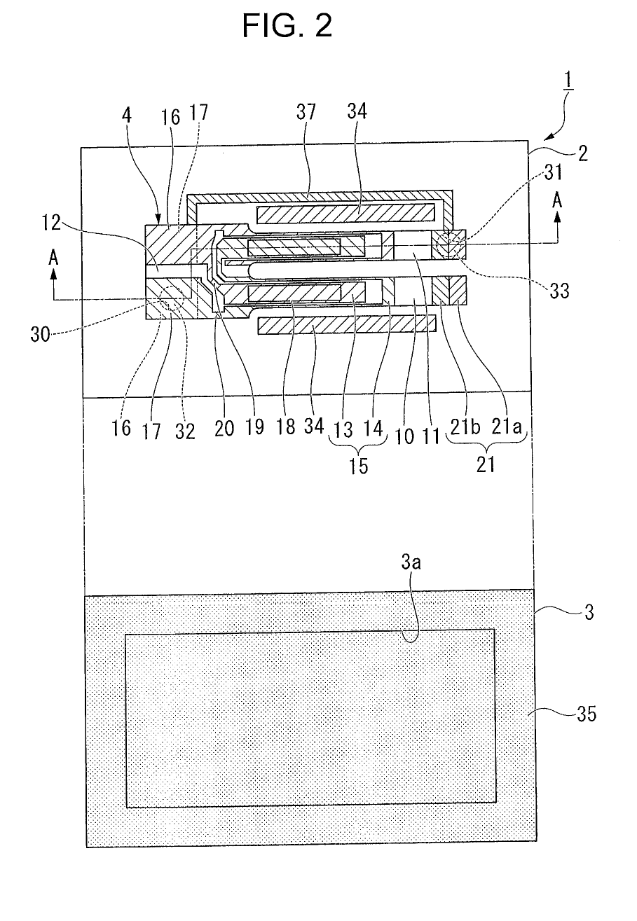

As shown in FIGS. 2 and 3, the base board 2 is formed with a pair of through-holes (penetration holes) 30 and 31 penetrating through the base board 2. The pair of through-holes 30 and 31 is formed at both ends of the diagonal line of the cavity C. The pair of through-holes 30 and 31 are formed with a pair of penetration electrodes 32 and 33 which are formed so as to bury the through-holes 30 and 31. The penetration electrodes 32 and 33 are made of a conductive material such as Ag paste. The lower surface of the base board 2 is formed with the pair of outer electrodes 38 and 39 which are electrically connected to the pair of penetration electrodes 32 and 33, respectively.

As shown in FIGS. 2 and 4, the upper surface side of the base board 2 (the bonding surface side to be bonded to the lid board 3) is patterned with the pair of lead-out electrodes 36 and 37 by a conductive material (for example, aluminum). The pair of lead-out electrodes 36 and 37 are patterned so that one penetration electrode 32 of the pair of penetration electrodes 32 and 33 is electrically connected to one mount electrode 16 of the piezoelectric vibrating reed 4, and the other penetration electrode 33 is electrically connected to the other mount electrode 17 of the piezoelectric vibrating reed 4.

Moreover, as shown in FIGS. 2 and 4, the piezoelectric vibrator 1 of the present embodiment is provided with a gettering material 34 which is formed in the base board 2 so as to be accommodated in the cavity C. The gettering material 34 is activated by laser irradiation to absorb surrounding gas and can be made from metal such as aluminum (Al), titanium (Ti), zirconium (Zr), or chromium (Cr) or alloys thereof.

The gettering material 34 is disposed at a position where laser irradiation can be performed from the outside of the piezoelectric vibrator 1. Since the bottom surfaces of recess portions 3a, described later, of the lid board 3 are non-polished surfaces (having a ground glass form), it is difficult to perform laser irradiation from the outside (the upper surface side of the piezoelectric vibrator 1) of the lid board 3. For this reason, laser irradiation is performed from the outer side (the lower surface side of the piezoelectric vibrator 1) of the base board 2. Therefore, the gettering material 34 is disposed at a position where it does not overlap with the outer electrodes 38 and 39 as viewed from the normal direction of the base board 2.

Furthermore, in the present embodiment, the gettering material 34 is disposed at a position where it does not overlap with the weight metal film 21 as viewed from the normal direction of the base board 2. In the example shown in the drawing, the gettering material 34 is disposed at both outer sides of the pair of vibrating arms 10 and 11 in the width direction of the piezoelectric vibrating reed 4 as viewed from the normal direction of the base board 2.

The lid board 3 is a transparent insulating board made of glass material, for example, soda-lime glass, similarly to the base board 2, as shown in FIGS. 1, 3, and 4, and is formed in a board-like form having a size capable of being superimposed onto the base board 2, as shown in FIGS. 1 to 4. In a bonding surface side thereof to be bonded with the base board 2, a rectangular recess portion 3a is formed in which the piezoelectric vibrating reed 4 is accommodated. The recess portion 3a is a recess portion for a cavity serving as the cavity C that accommodates the piezoelectric vibrating reed 4 when the two boards 2 and 3 are superimposed onto each other. The lid board 3 is anodically bonded to the base board 2 in a state where the recess portion 3a faces the base board 2.

As shown in FIGS. 1 to 4, the piezoelectric vibrator 1 of the present embodiment is provided with a bonding film 35 which is formed over an entire surface of the lid board 3 on the opposite side to the base board 2 so as to bond both boards 2 and 3 to each other at a portion thereof being in contact with the base board 2. As shown in FIGS. 2 and 3, the bonding film 35 of the present embodiment is formed over the entire surfaces of the surface that defines the recess portion 3a and the peripheral surface of the bonding surface of the lid board 2 extending continuously along the outer periphery of the recess portion 3a. Among these bonding surfaces, a portion of the bonding film 35 formed on the peripheral portion of the bonding surface is bonded to the base board 3.

In the present embodiment, the bonding film 35 is formed of a material which is capable of absorbing surrounding gas by being activated with laser irradiation. The bonding film 35 is formed of a material which is capable of achieving anodic bonding of both boards 2 and 3. As such a material of the bonding film 35, aluminum can be used, for example.

Moreover, the gettering material 34 and the bonding film 35 are formed of different materials. In the present embodiment, for example, the gettering material 34 is formed of a material (e.g., chromium) that effectively improves the degree of vacuum in the cavity C through gettering. The bonding film 35 is formed of a material (e.g., aluminum) that tightly bonds the base board 2 and the lid board 3 together.

When the piezoelectric vibrator 1 configured in this manner is operated, a predetermined drive voltage is applied between the outer electrodes 38 and 39 which are formed on the base board 2. In this way, a voltage can be applied to the excitation electrode 15 including the first excitation electrode 13 and the second excitation electrode 14 of the piezoelectric vibrating reed 4, and the pair of vibrating arms 10 and 11 are allowed to vibrate at a predetermined frequency in a direction to move closer to or away from each other. This vibration of the pair of vibrating arms 10 and 11 can be used as the time source, the timing source of a control signal, the reference signal source, and the like.

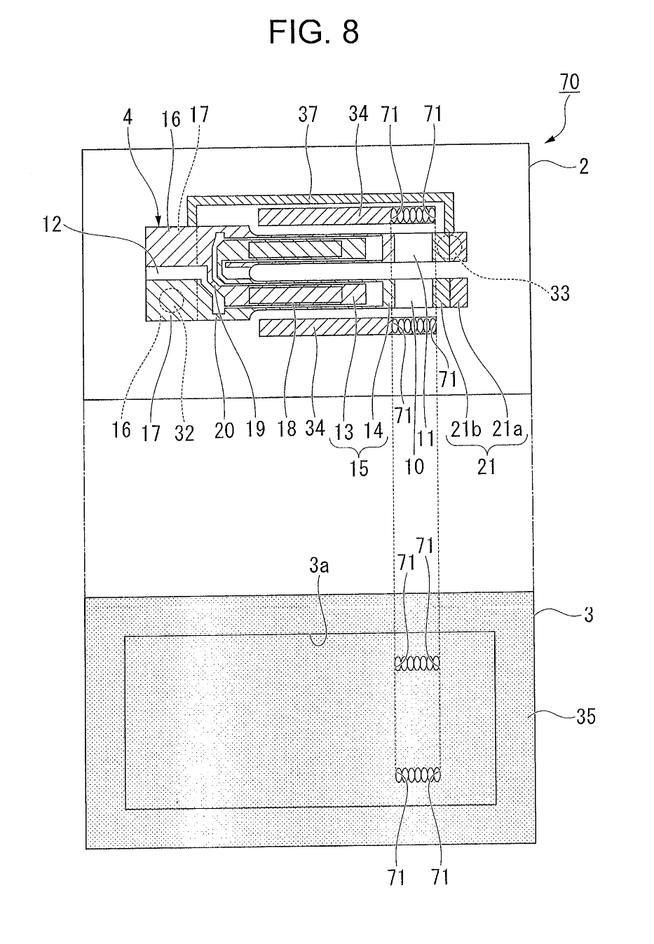

Next, description of a piezoelectric vibrator 70 will be provided which is a finished product having improved the degree of vacuum in the cavity C by performing a gettering step of the manufacturing method of a piezoelectric vibrator described later on the piezoelectric vibrator 1 which is a work in process as shown in FIG. 8.

The gettering material 34 and the bonding film 35 of the piezoelectric vibrator 70 are simultaneously irradiated with a laser beams, and first laser irradiation marks 71 are formed thereon. In the present embodiment, a plurality of first laser irradiation marks 71 is formed at positions of the gettering material 34 and the bonding film 35 facing each other in the normal direction of the base board 2.

The first laser irradiation marks 71 are formed when the gettering material 34 (or the bonding film 35) is irradiated with a laser beam and the gettering material 34 (or the bonding film 35) is evaporated and removed. For example, when one point of the gettering material 34 (or the bonding film 35) is irradiated (point-irradiated) with a laser beam, the laser irradiation mark 71 is formed in a bowl shape. Moreover, when the point-irradiation is repeated by scanning the laser beam at a short distance, the laser irradiation marks 71 are formed in a groove shape.

### Manufacturing Method of Piezoelectric Vibrator

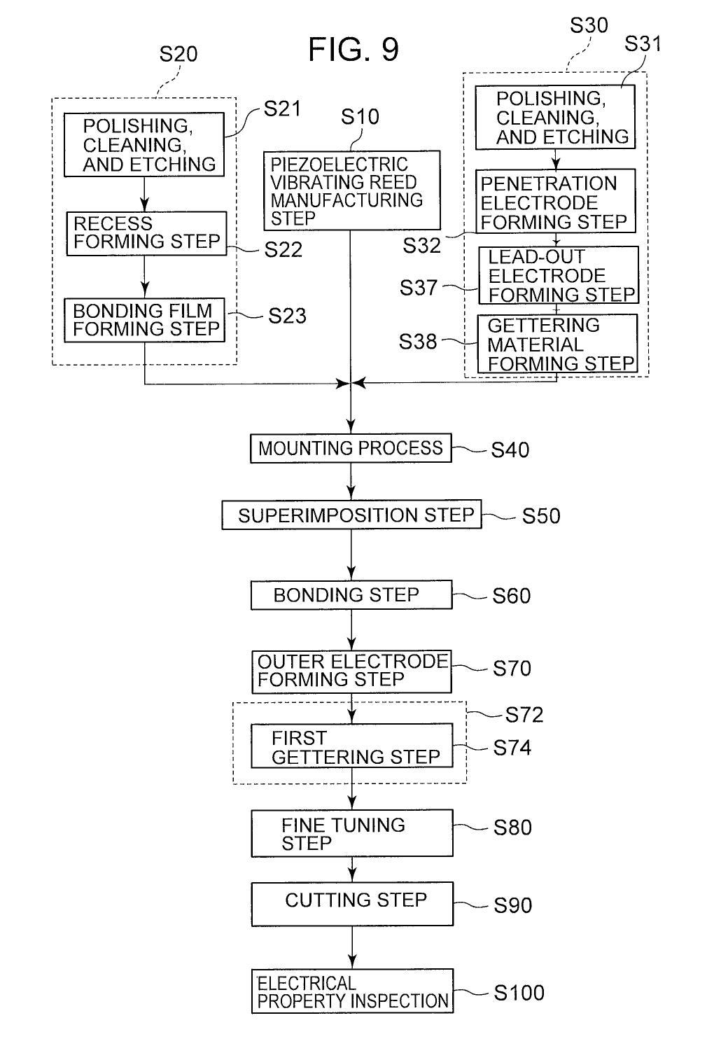

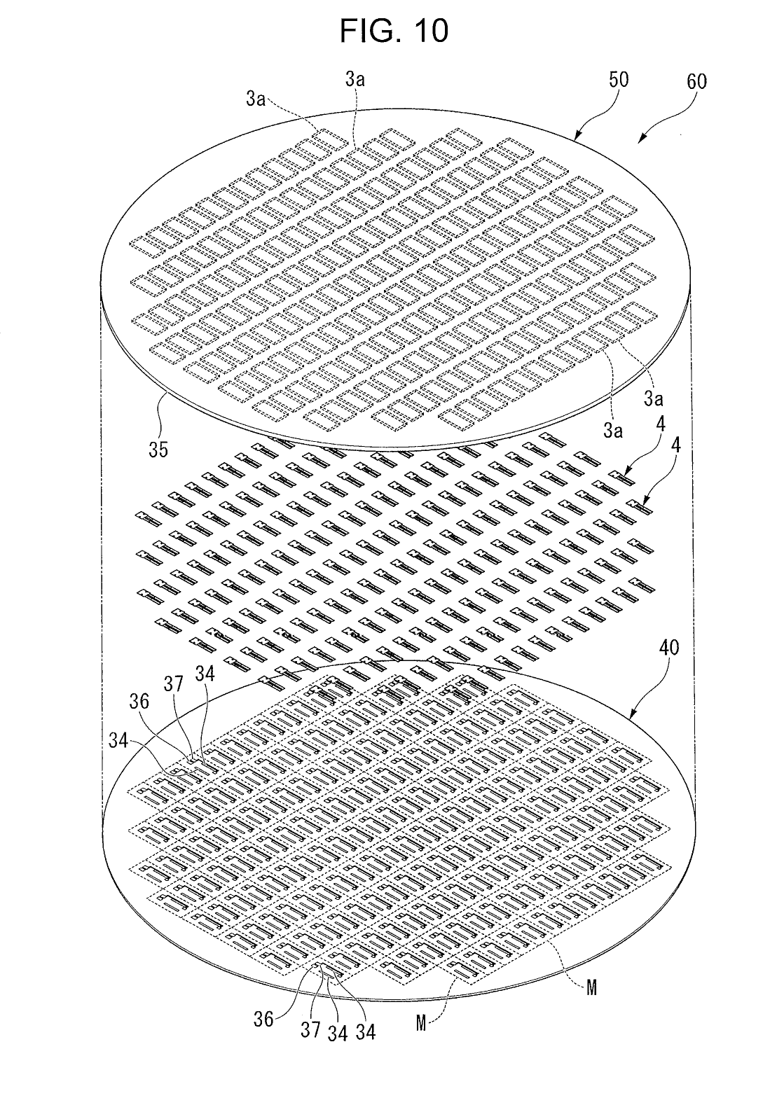

Next, a method for manufacturing the above-described piezoelectric vibrator 1 will be described with reference to FIGS. 9 and 10. The dotted line M shown in FIG. 10 is a cutting line along which a cutting step performed later is achieved. In the present embodiment, a plurality of piezoelectric vibrators 1 and 70 is manufactured at a time by disposing a plurality of piezoelectric vibrating reeds 4 between a base board wafer (base board) 40 and a lid board wafer (lid board) 50.

First, a piezoelectric vibrating reed manufacturing step is performed to manufacture the piezoelectric vibrating reed 4 shown in FIGS. 5 to 7 (S10). Moreover, after the piezoelectric vibrating reed 4 is manufactured, rough tuning of a resonance frequency is performed. This rough tuning is achieved by irradiating the rough tuning film 21a of the weight metal film 21 with a laser beam to evaporate in part the rough tuning film 21a, thus changing a weight thereof. Fine tuning of adjusting the resonance frequency more accurately is performed after a mounting step is performed. This fine tuning will be described later.

Subsequently, as shown in FIG. 10, a first wafer manufacturing step is performed where the lid board wafer 50 serving as the lid board is manufactured up to a stage immediately before anodic bonding is achieved (S20).

In this step, first, a disk-shaped lid board wafer 50 is formed by polishing a soda-lime glass to a predetermined thickness, cleaning the polished glass, and removing an affected uppermost layer by etching or the like (S21). Subsequently, a recess forming step is performed where a plurality of recess portions 3a to be used as a cavity is formed in a matrix form on a bonding surface of the lid board wafer 50 by etching or the like (S22). After that, a bonding film forming step is performed where a material (e.g., aluminum) capable of absorbing surrounding gas by being activated with laser irradiation and with the possibility of anodic bonding is patterned over the entire surface on the bonding surface side of the lid board wafer 50 (S23). The first wafer manufacturing step ends at this point in time.

Subsequently, at the same or a different time as the first wafer manufacturing step, a second wafer manufacturing step is performed where a base board wafer 40 later serving as the base board is manufactured up to a stage immediately before anodic bonding is achieved (S30).

In this step, first, a disk-shaped base hoard wafer 40 is formed by polishing a soda-lime glass to a predetermined thickness, cleaning the polished glass, and removing an affected uppermost layer by etching or the like (S31). Subsequently, a penetration electrode forming step is performed where a plurality of pairs of penetration electrodes 32 and 33 is formed on the base board wafer 40 (S32).

Subsequently, as shown in FIG. 4, a lead-out electrode forming step is performed where a conductive material is patterned on the upper surface of the base board wafer 40 so as to form lead-out electrodes 36 and 37 (S37). At the same time, a gettering material forming step takes place where a gettering material 34 is formed (S38). The lead-out electrode forming step (S37) and the gettering material forming step (S38) may precede each other. Moreover, the steps may be performed at the same time if the lead-out electrodes 36 and 37 and the gettering material 34 are formed of the same materials.

The second wafer manufacturing step ends at this point in time.

Subsequently, a mounting step is performed where a plurality of manufactured piezoelectric vibrating reeds 4 is bonded to the upper surface of the base board wafer 40 via the lead-out electrodes 36 and 37 (S40). First, bumps B made of gold or the like are formed on the pair of lead-out electrodes 36 and 37. The base portion 12 of the piezoelectric vibrating reed 4 is placed on the bumps B, and thereafter the piezoelectric vibrating reed 4 is pressed against the bumps B while heating the bumps B to a predetermined temperature. In this way, the piezoelectric vibrating reed 4 is mechanically supported by the bumps B to be floated from the upper surface of the base board wafer 40, and the mount electrodes 16 and 17 are electrically connected to the lead-out electrodes 36 and 37.

After the piezoelectric vibrating reed 4 is mounted, a superimposition step is performed where the lid board wafer 50 is superimposed onto the base board wafer 40 as shown in FIG. 10 (S50). Specifically, both wafers 40 and 50 are aligned at a correct position using reference marks or the like not shown in the figure as indices. In this way, the mounted piezoelectric vibrating reed 4 is accommodated in the cavity C which is formed between both wafers 40 and 50.

After the superimposition step is performed, a bonding step is performed where the two superimposed wafers 40 and 50 are inserted into an anodic bonding machine not diagrammatically included to achieve anodic bonding under a predetermined temperature atmosphere with application of a predetermined voltage (S60). Specifically, a predetermined voltage is applied between the bonding film 35 and the lid board wafer 50. Then, an electrochemical reaction occurs at an interface between the bonding film 35 and the lid board wafer 50, whereby they are closely adhered tightly and anodically bonded. In this way, the piezoelectric vibrating reed 4 can be sealed in the cavity C, and a wafer assembly 60 can be obtained in which the base board wafer 40 and the lid board wafer 50 are bonded to each other.

After the anodic bonding is completed, an outer electrode forming step is performed where a conductive material is patterned onto the lower surface of the base board wafer 40 so as to form a plurality of pairs of outer electrodes 38 and 39 (S70). By this step, the wafer assembly 60 in which a plurality of piezoelectric vibrators 1 is connected to each other can be formed. The piezoelectric vibrating reed 4 which is sealed in the cavity C can be operated via the penetration electrodes 32 and 33 from the outer electrodes 38 and 39.

Subsequently, a gettering step is performed where the bonding film 35 is activated by irradiating at least the bonding film 35 with a laser beam (S72). As a laser source, a YAG laser or the like can be used similar to that used in a fine tuning step described later. As described above, since laser irradiation cannot be performed from the outside of the lid board wafer 50, the laser irradiation is performed from the outside of the base board wafer 40. When the bonding film 35 (e.g., Al) is evaporated by the laser irradiation, the bonding film 35 absorbs oxygen in the cavity C to form metal oxides (e.g., Al₂O₃). In this way, oxygen in the cavity C is consumed, whereby the degree of vacuum can be increased to a certain level or more. Here, a certain level means a state where a series resonance resistance value does not change greatly even when the degree of vacuum is increased further. In this way, a suitable series resonance resistance value can be ensured.

In the present embodiment, the gettering step includes a first gettering step (S74) where the gettering material 34 and the bonding film 35 are irradiated with a laser beam at the same time.

In this step, the gettering material 34 and the bonding film 35 are irradiated with a laser beam along the normal direction of the base board wafer 40 from the outer side of the base board wafer 40. Moreover, at this time, the series resonance resistance value may be measured while applying a voltage to the pair of outer electrodes 38 and 39 which are formed on the lower surface of the base board wafer 40 and allowing the piezoelectric vibrating reed 4 to vibrate.

In the gettering step of the present embodiment, the first gettering step is performed repeatedly until it is determined that a suitable series resonance resistance value is ensured, namely until it is determined that the degree of vacuum in the cavity C has increased to a predetermined level or more. The series resonance resistance value may be determined based on, for example, the measured series resonance resistance value and may be determined based on the size of the surface areas of the laser-irradiated regions of the gettering material 34 and the bonding film 35.

In this way, the piezoelectric vibrators 70, in which the first laser irradiation marks 71 are formed on the gettering material 34 and the bonding film 35, are formed in a state where they are connected in a wafer shape.

Subsequently, a fine tuning step is performed where the frequencies of the piezoelectric vibrating reeds 4 sealed in the cavities C are tuned finely to fall within a predetermined range (S80). Specifically, a voltage is applied to the pair of outer electrodes 38 and 39 which are formed on the lower surface of the base board wafer 40, thus allowing the piezoelectric vibrating reeds 4 to vibrate. A laser beam is irradiated onto the base board wafer 40 from the outer side while measuring the vibration frequencies to evaporate and trim the fine tuning film 21b of the weight metal film 21. When the fine tuning film 21b is trimmed, since the weight on the tip ends of the pair of vibrating arms 10 and 11 decreases, the frequency of the piezoelectric vibrating reed 4 increases. In this way, the fine tuning can be performed in such a way that the frequency of the piezoelectric vibrating reed 4 falls within the predetermined range of the nominal frequency.

After the fine tuning of the frequency is completed, a cutting step is performed where the wafer assembly 60 shown in FIG. 10 is cut along the cutting line M to obtain small fragments (S90). As a result, a plurality of two-layered SMD-type piezoelectric vibrators 70 shown in FIG. 8, in which the piezoelectric vibrating reed 4 is sealed in the cavity C formed between the base board 2 and the lid board 3 being anodically bonded together, can be manufactured at a time.

The gettering step (S72) and the fine tuning step (S80) may be performed after performing the cutting step (S90) to obtain the individual fragments of the piezoelectric vibrators 70. However, as described above, by performing the gettering step (S72) and the fine tuning step (S80) earlier, since the gettering step and the fine tuning step can be performed on the wafer assembly 60, it is possible to manufacture the plurality of piezoelectric vibrators 70 more efficiently. Therefore, it is desirable because throughput can be increased.

Subsequently, an electrical property test of the piezoelectric vibrating reed 4 is conducted (S100). That is, the resonance frequency, resonance resistance value, drive level properties (the excitation power dependence of the resonance frequency and the resonance resistance value), and the like of the piezoelectric vibrating reed 4 are measured and checked. Moreover, the insulation resistance properties and the like are compared and checked as well. Finally, an external appearance test of the piezoelectric vibrator 70 is conducted to check the dimensions, the quality, and the like. In this way, the manufacturing of the piezoelectric vibrator 70 ends.

As described above, according to the piezoelectric vibrator 1, namely the piezoelectric vibrator 1 as the work in process, of the present embodiment, the bonding film 35 is formed of a material capable of absorbing surrounding gas by being activated with laser irradiation. Therefore, by activating the portion of the bonding film 35 positioned inside the cavity C with laser irradiation, the gas in the cavity C can be absorbed and gettered, and thus the degree of vacuum in the cavity C can be increased. Accordingly, the gettering can be achieved by irradiating the bonding film 35 as well as the gettering material 34 with a laser beam, and the degree of vacuum in the cavity C can be ensured when compared to the case of gettering only the gettering material 34.

Moreover, such an operational advantage can be obtained without increasing the formation area of the gettering material 34 on the base board 2. Furthermore, since the bonding film 35 only needs to be formed over the entire surface of the lid board 3 facing the base board 2, the piezoelectric vibrator 1 can be manufactured more efficiently compared to the case of forming another gettering material, for example, used for only gettering on the lid board 3.

Moreover, the gettering material 34 and the bonding film 35 are formed of different materials. Furthermore, in the present embodiment, the gettering material 34 is formed of a material (e.g., chromium) capable of effectively increasing the degree of vacuum in the cavity C by gettering. The bonding film 35 is formed of a material (e.g., aluminum) capable of tightly bonding the base board 2 and the lid board 3 to each other. Therefore, it is possible to increase effectively the degree of vacuum in the cavity C by gettering while ensuring the sealing state of the cavity C with bonding of the bonding film 35.

Moreover, according to the manufacturing method of the piezoelectric vibrator of the present embodiment, since the gettering material 34 and the bonding film 35 are irradiated with a laser beam at the same time in the first gettering step, the gettering effect can be doubled by one laser irradiation instance. Therefore, it is possible to perform the gettering effectively while ensuring the degree of the vacuum in the cavity C.

Furthermore, according to the piezoelectric vibrator 70, namely the piezoelectric vibrator 70 as the finished product, of the present embodiment, since the degree of vacuum in the cavity C can be ensured, it is possible to decrease the series resonance resistance value to a suitable value and suppress production of defective products to increase yield.

### Second Embodiment

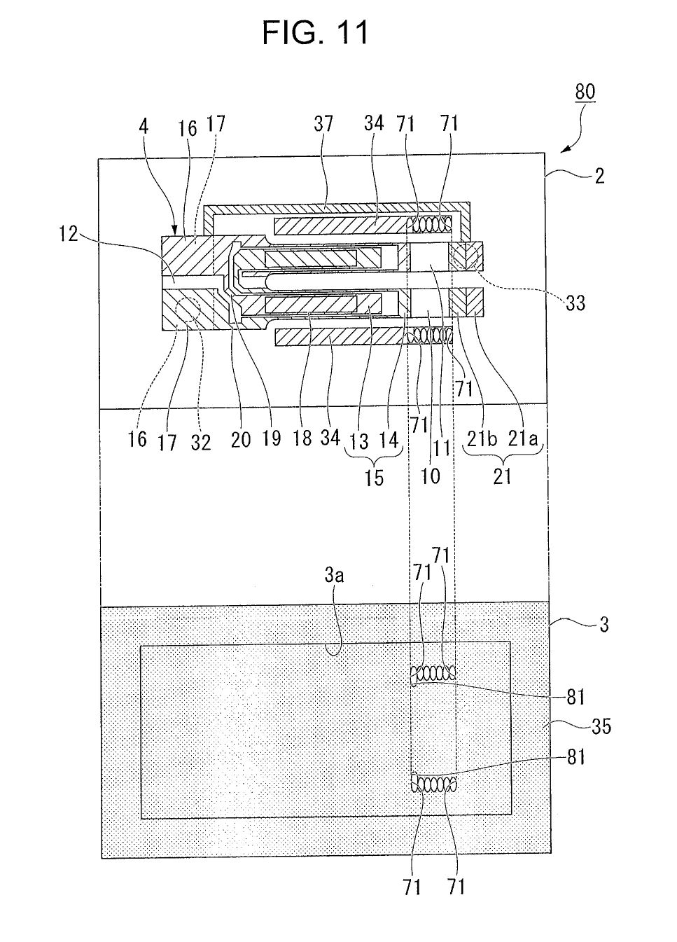

Next, a piezoelectric vibrator according to a second embodiment of the present invention will be described with reference to FIG. 11.

In the second embodiment, the same constituent elements as those in the first embodiment will be denoted by the same reference numerals, and description thereof will be omitted and only the points of difference will be described.

In a piezoelectric vibrator 80 of the present embodiment, second laser irradiation marks 81 are formed at portions of the bonding film 35 in the cavity C where they do not overlap with the gettering material 34 as viewed from the normal direction of the base board 2.

In the example shown in the drawing, the second laser irradiation marks 81 are formed to be adjacent or continuous to a part of the first laser irradiation marks 71. Moreover, the second laser irradiation marks 81 are formed at positions where they do not overlap with the piezoelectric vibrating reed 4, the penetration electrodes 32 and 33, the lead-out electrodes 36 and 37, and the outer electrodes 38 and 39 as viewed from the normal direction of the base board 2.

Similar to the first laser irradiation marks 71 formed on the bonding film 35, the second laser irradiation mark 81 is formed when the bonding film 35 is irradiated with a laser beams and the bonding film 35 is evaporated and removed.

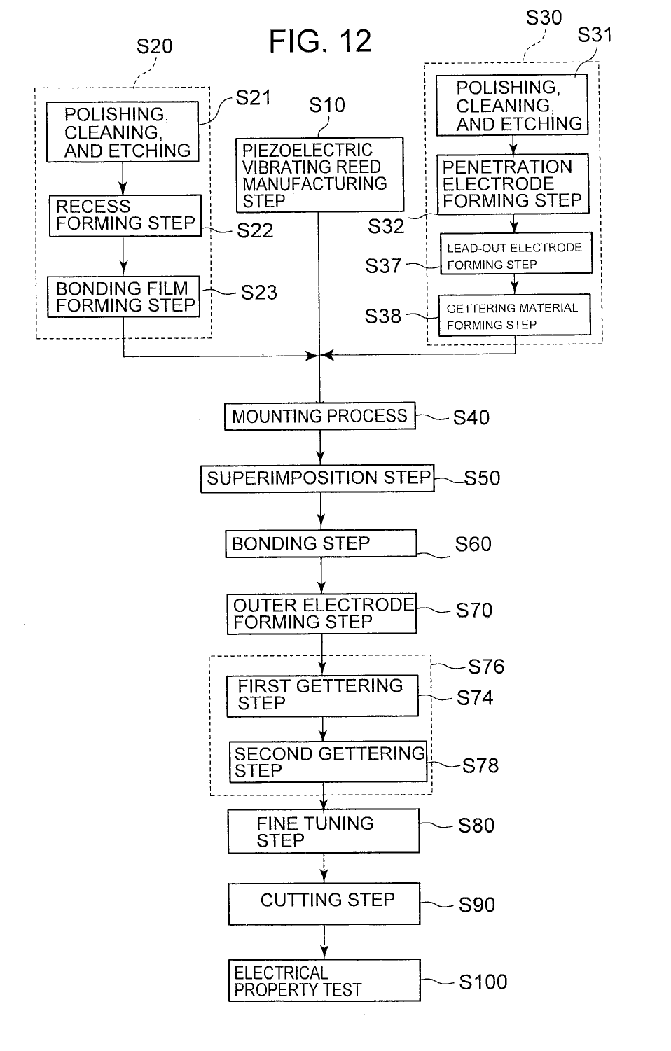

Next, the manufacturing method of the piezoelectric vibrator 80 according to the present embodiment will be described with reference to the flowchart of FIG. 12. In the following description, a gettering step (S76) according to the present embodiment will be described with reference to the flowchart. The gettering step includes the first gettering step (S74) described above and a second gettering step (S78) where a laser beam is irradiated onto portions of the bonding film 35 in the cavity C where they do not overlap with the gettering material 34 as viewed from the normal direction of the base board 2.

Specifically, the gettering step (S76) starts with the first gettering step (S74). In the first gettering step, first, a predetermined range of areas of the gettering material 34 and the bonding film 35 is irradiated with a laser beam to form the first laser irradiation marks 71. Subsequently, a voltage is applied to the pair of outer electrodes 38 and 39 to vibrate the piezoelectric vibrating reed 4, and the series resonance resistance value is measured. After that, a difference between the measured series resonance resistance value and a suitable series resonance resistance value is calculated.

Subsequently, based on the difference between the measured series resonance resistance value and the suitable series resonance resistance value, namely the difference between the current degree of vacuum in the cavity C and a suitable degree of vacuum (a predetermined vacuum level), it is determined whether the first gettering step (S74) will be repeated, the second gettering step (S78) will be performed, or the gettering step (S76) will be stopped.

Here, in the second gettering step (S78), since a laser beam is irradiated onto portions of the bonding film 35 in the cavity C where they do not overlap with the gettering material 34 as viewed from the normal direction of the base board 2 to form the second laser irradiation marks 81, only the bonding film 35 is gettered. Therefore, the degree of vacuum in the cavity C is increased by a smaller amount than the first gettering step.

Therefore, at this time, based on the difference between the measured series resonance resistance value and the suitable series resonance resistance value, a determination is made as follows. That is to say, when the difference is small enough to make unnecessary the increasing of the degree of vacuum in the cavity C, the gettering step (S76) ends. Moreover, when the difference is great enough to necessitate the second gettering step to increase the degree of vacuum in the cavity C, the second gettering step (S78) is performed. In other cases, the first gettering step (S74) is performed.

The second gettering step is performed until the suitable series resonance resistance value is ensured. Moreover at this time, a laser beam may be irradiated onto portions of the gettering material 34 where they are adjacent or continuous to a part of the first laser irradiation marks 71 formed by the first gettering step. Furthermore, at this time, the laser beam may be irradiated onto portions where they do not overlap with the piezoelectric vibrating reed 4, the lead-out electrodes 36 and 37, and the outer electrodes 38 and 39 as viewed from the normal direction of the base board 2.

As described above, according to the manufacturing method of the piezoelectric vibrator of the present embodiment, the first gettering step or the second gettering step is performed based on the series resonance resistance value which is correlated with the degree of vacuum in the cavity C. Therefore, it is possible to finely adjust the extent of increasing the degree of vacuum in the cavity C and to thus adjust the degree of vacuum with high precision.

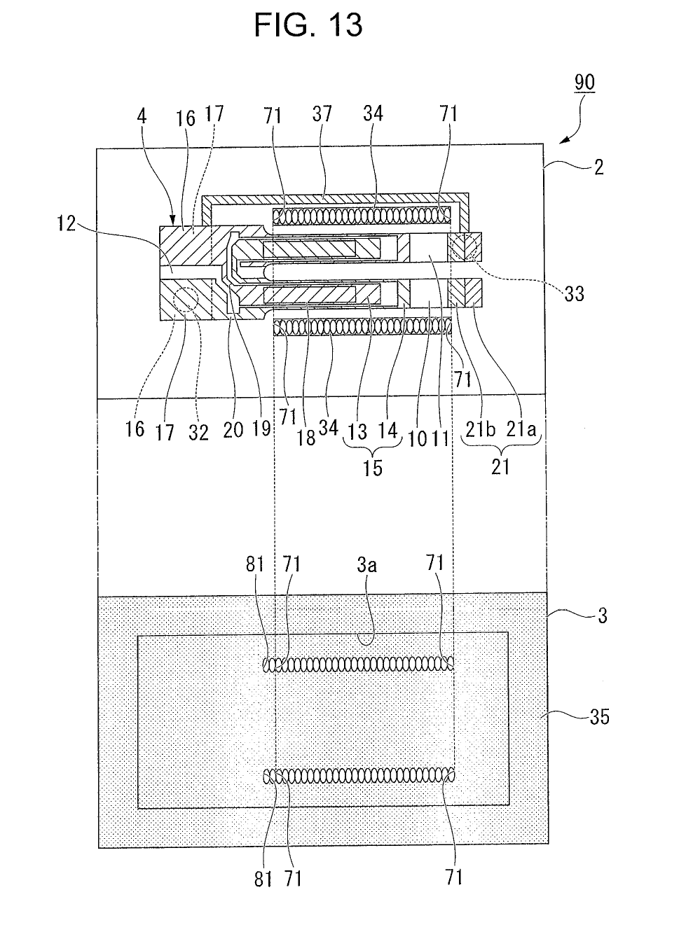

Moreover, similar to the piezoelectric vibrator 90 shown in FIG. 13, even when the entire areas of the gettering material 34 are irradiated with a laser beam in the first gettering step, by gettering the bonding film 35 in the second gettering step, it is possible to increase the degree of vacuum in the cavity C further.

Although in the present embodiment, the first gettering step is performed while measuring the series resonance resistance value and the step to be performed subsequently is determined based on the difference between the measured series resonance resistance value and the suitable series resonance resistance value, the present invention is not limited to this. For example, the determination may be made based on the size of surface areas of the laser-irradiated regions of the gettering material 34 and the bonding film 35.

Moreover, although in the present embodiment, the second laser irradiation marks 81 are formed to be adjacent or continuous to a part of the first laser irradiation marks 71, they may not be continuous. Furthermore, the second laser irradiation marks 81 are formed at positions where they do not overlap with the piezoelectric vibrating reed 4, the lead-out electrodes 36 and 37, and the outer electrodes 38 and 39 as viewed from the normal direction of the base board 2, they may overlap with each other.

### Oscillator

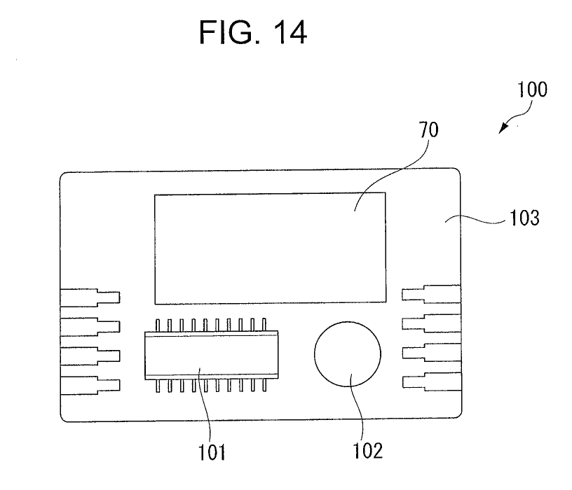

Next, an oscillator according to an embodiment of the present invention will be described with reference FIG. 14.

In the following embodiments, the piezoelectric vibrator 70 according to the first embodiment is used as the piezoelectric vibrator. However, the same operational effect can be obtained with the piezoelectric vibrators 80 and 90 according to the second embodiment.

As shown in FIG. 14, an oscillator 100 of the present embodiment is one in which the piezoelectric vibrator 70 is configured as an oscillating piece that is electrically connected to an integrated circuit 101. The oscillator 100 includes a board 103 on which an electronic component 102 such as a capacitor is mounted. The integrated circuit 101 for the oscillator is mounted on the board 103, and the piezoelectric vibrating reed 4 of the piezoelectric vibrator 70 is mounted in the vicinity of the integrated circuit 101. The electronic component 102, integrated circuit 101, and piezoelectric vibrator 70 are electrically connected by a wiring pattern which is not shown. It should be noted that these components are molded by resin which is not shown.

In the oscillator 100 configured in this manner, the piezoelectric vibrating reed 4 in the piezoelectric vibrator 70 vibrates when a voltage is applied to the piezoelectric vibrator 70. This vibration is converted to an electrical signal by the piezoelectric properties of the piezoelectric vibrating reed 4 and is then input to the integrated circuit 101 as the electrical signal. The input electrical signal is subjected to various kinds of processing by the integrated circuit 101 and is then output as a frequency signal. In this way, the piezoelectric vibrator 70 functions as an oscillating piece.

By selectively setting the configuration of the integrated circuit 101, for example, an RTC (Real Time Clock) module, according to the demands, it is possible to add a function of controlling the date or time for operating the device or an external device or providing the time or calendar other than a single-function oscillator for a clock.

According to the present embodiment, since the oscillator 100 includes the piezoelectric vibrator 70 having improved yield, it is possible to reduce the cost of the oscillator 100.

### Electronic Device

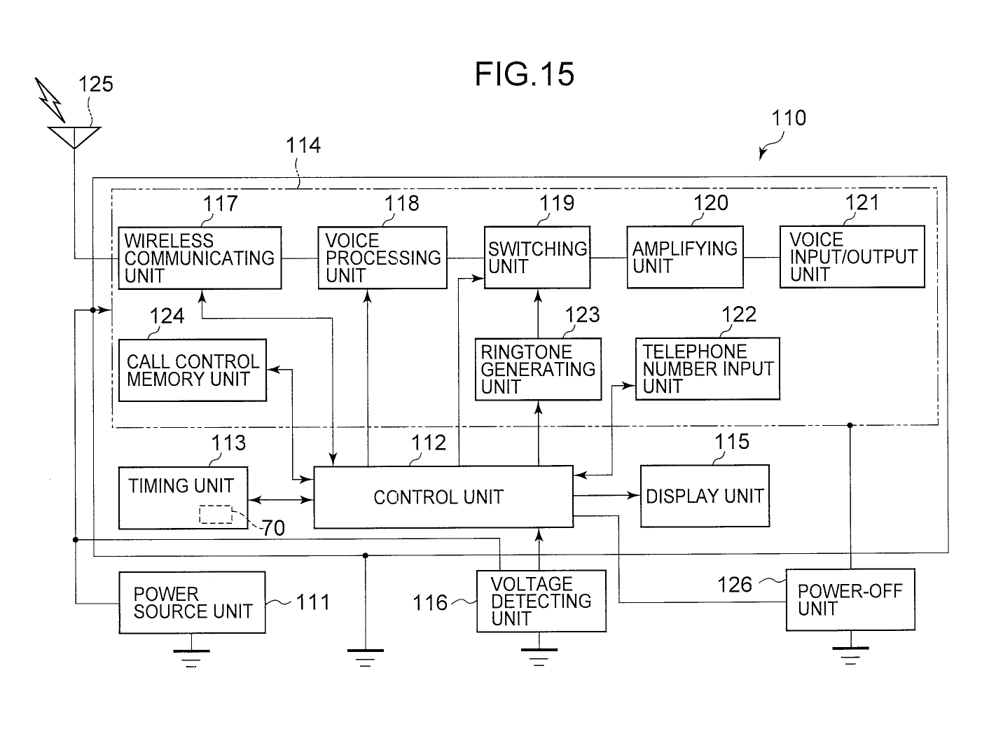

Next, an electronic device according to an embodiment of the present invention will be described with reference to FIG. 15. The present embodiment will be described by way of the example of a portable information device 110 having the piezoelectric vibrator 70 as an example of the electronic device. First, the portable information terminal 110 of the present embodiment is represented, for example, by a cellular phone and is one that is developed and improved upon a wristwatch of the related art. The portable information device 110 looks like a wristwatch in external appearance and is provided with a liquid crystal display at a portion corresponding to the dial pad and is capable of displaying the current time or the like on the screen. When the portable information device 110 is used as a communication tool, the user removes it from the wrist and makes the same communications as with a cellular phone of the related art using the internal speaker and microphone on the inner side of its strap. However, the portable information device is remarkably small and light compared with the cellular phone of the related art. Next, the configuration of the portable information device 110 of the present embodiment will be described. As shown in FIG. 15, the portable information device 110 includes the piezoelectric vibrator 70 and a power supply portion 111 for supplying power. The power supply portion 111 is formed, for example, of a lithium secondary battery. The power supply portion 111 is connected in parallel to a control portion 112 that performs various kinds of control, a time counting portion 113 that measures the time or the like, a communication portion 114 that makes communications with the outside, a display portion 115 that displays various kinds of information, and a voltage detection portion 116 that detects voltages at the respective function portions. The power supply portion 111 supplies power to the respective functional portions.

The control portion 112 controls the respective function portions so as to control operations of the overall system, such as operations to transmit and receive audio data and operations to count and display the current time. The control portion 112 includes a ROM in which a program is written in advance, a CPU that reads out and runs the program written to the ROM, a RAM used as a work area of the CPU, and the like.

The time counting portion 113 includes an integrated circuit enclosing an oscillation circuit, a register circuit, a time counting circuit, and an interface circuit, and the like as well as the piezoelectric vibrator 70. When a voltage is applied to the piezoelectric vibrator 70, the piezoelectric vibrating reed 4 vibrates, and this vibration is converted to an electrical signal by the piezoelectric properties of the quartz crystal and is input to the oscillation circuit as the electrical signal. The output of the oscillation circuit is converted to a digital form and counted by the register circuit and the time counting circuit. Signals are transmitted and received to and from the control portion 112 via the interface circuit, and the current time and the current date or the calendar information or the like are displayed on the display portion 115.

The communication portion 114 is provided with the same functions as those of the cellular phone of the related art, and includes a wireless portion 117, an audio processing portion 118, a switching portion 119, an amplifier portion 120, an audio input/output portion 121, a telephone number input portion 122, a ring tone generation portion 123, and a call control memory portion 124.

The wireless portion 117 carries out transmission and reception of various kinds of data, such as audio data, with the base station via an antenna 125. The audio processing portion 118 encodes and decodes an audio signal input therein from the wireless portion 117 or the amplifier portion 120. The amplifier portion 120 amplifies a signal input therein from the audio processing portion 118 or the audio input/output portion 121 to a specific level. The audio input/output portion 121 is formed of a speaker and a microphone and the like, and makes a ring tone and incoming audio louder as well as collects audio.

The ring tone generation portion 123 generates a ring tone in response to a call from the base station. The switching portion 119 switches the amplifier portion 120 normally connected to the audio processing portion 118 to the ring tone generation portion 123 only when a call arrives, so that the ring tone generated in the ring tone generation portion 123 is output to the audio input/output portion 121 via the amplifier portion 120.

The call control memory portion 124 stores a program relating to incoming and outgoing call control for communications. The telephone number input portion 122 includes, for example, numeric keys from 0 to 9 and other keys and the user inputs the telephone number of the communication receiver by depressing these numeric keys and the like.

The voltage detection portion 116 detects a voltage drop when a voltage being applied to each function portion, such as the control portion 112, by the power supply portion 111 drops below the predetermined value, and notifies the control portion 112 of the detection. The predetermined voltage value referred to herein is a value pre-set as the lowest voltage necessary to operate the communication portion 114 in a stable manner, for example, about 3 V. Upon receipt of a notification of a voltage drop from the voltage detection portion 116, the control portion 112 disables the operation of the wireless portion 117, the audio processing portion 118, the switching portion 119, and the ring tone generation portion 123. In particular, it is essential to stop the operation of the wireless portion 117 that consumes a large amount of power. Furthermore, a message informing that the communication portion 114 is unavailable due to insufficient battery power is displayed on the display portion 115.

More specifically, it is possible to disable the operation of the communication portion 114 and display the notification message on the display portion 115 by the voltage detection portion 116 and the control portion 112. This message may be displayed as a character message, or as a more intuitive indication, which may be displayed by putting a cross mark on the telephone icon displayed at the top of the display screen of the display portion 115.

By providing a power shutdown portion 126 capable of selectively shutting down the power supply to portions involved with the function of the communication portion 114, it is possible to stop the function of the communication portion 114 in a more reliable manner.

According to the present embodiment, since the portable information device 110 includes the piezoelectric vibrator 70 having improved yield, it is possible to reduce the cost of the portable information device 110.

### Radio-Controlled Clock

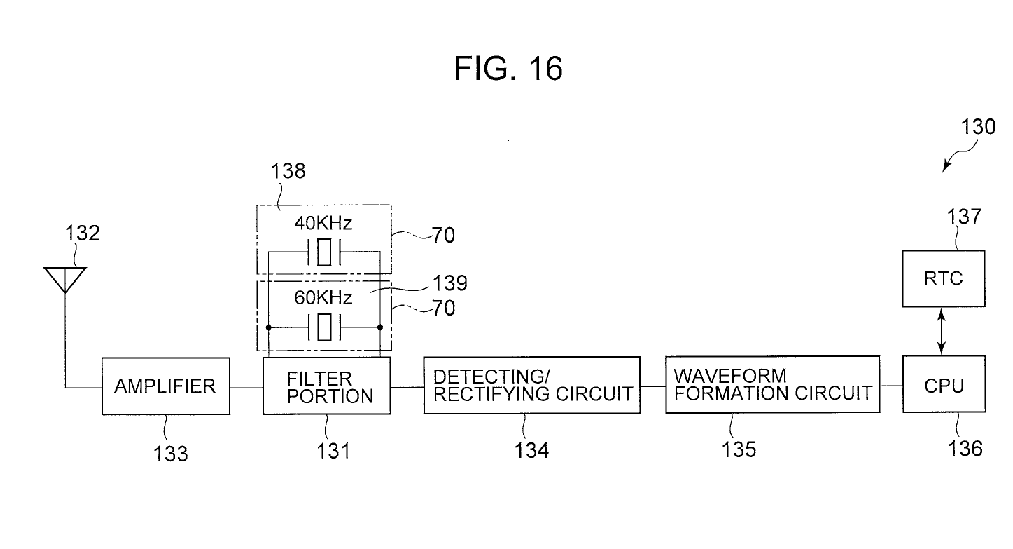

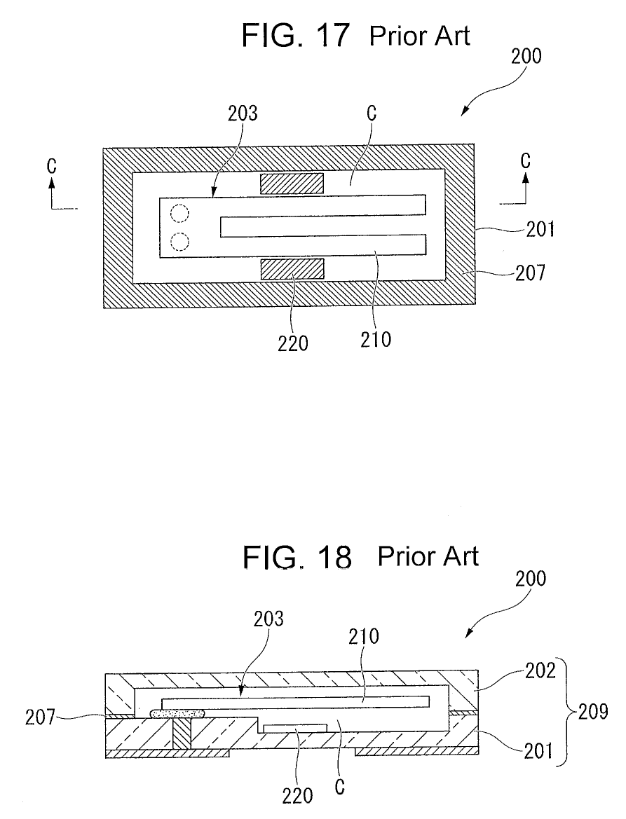

Next, a radio-controlled clock according to an embodiment of the present invention will be described with reference to FIG. 16.

As shown in FIG. 16, a radio-controlled clock 130 of the present embodiment includes the piezoelectric vibrators 70 electrically connected to a filter portion 131. The radio-controlled clock 130 is a clock provided with the function of displaying the correct time by automatically correcting the time upon receipt of a standard radio wave including the clock information.

In Japan, there are transmission centers (transmission stations) that transmit a standard radio wave in Fukushima Prefecture (40 kHz) and Saga Prefecture (60 kHz), and each center transmits the standard radio wave. A wave as long as 40 kHz or 60 kHz is of a kind to propagate along the land surface and of a kind to propagate while reflecting between the ionospheric layer and the land surface, and therefore has a propagation range wide enough to cover all Japan through the two transmission centers.

Hereinafter, the functional configuration of the radio-controlled clock 130 will be described in detail.

An antenna 132 receives the long standard radio wave at 40 kHz or 60 kHz. The long standard radio wave is made up of time information called a time code which is modulated by the AM modulation scheme and carried on a carrier wave of 40 kHz or 60 kHz. The received long standard wave is amplified by an amplifier 133 and filtered and synchronized by the filter portion 131 having a plurality of piezoelectric vibrators 70. In the present embodiment, the piezoelectric vibrators 70 include quartz vibrator portions (piezoelectric vibrating reeds) 138 and 139 having resonance frequencies at 40 kHz and 60 kHz which are the same as the carrier frequency.

Furthermore, the filtered signal at the specific frequency is detected and demodulated by a detection and rectification circuit 134. Subsequently, the time code is extracted by a waveform shaping circuit 135 and counted by the CPU 136. The CPU 136 reads out information about the current year, the total number of days, the day of the week, and the time and the like. The read information is reflected on the RTC 137 and the precise time information is displayed.

Because the carrier wave is 40 kHz or 60 kHz, a vibrator having the tuning-fork structure described above is suitable for the quartz vibrator portions 138 and 139.

Although the above description has been given of the example in Japan, the frequency of the long standard wave is different overseas. For example, a standard wave of 77.5 kHz is used in Germany. When the radio-controlled clock 130 operable as well overseas is incorporated into a portable device, the piezoelectric vibrator 70 set at the frequency different from the frequencies used in Japan is required.

According to the present embodiment, since the radio-controlled clock 130 includes the piezoelectric vibrator 70 having improved yield, it is possible to reduce the cost of the radio-controlled clock 130.

It should be noted that the technical scope of the present invention is not limited to the embodiments above, and the present invention can be modified in various ways without departing from the spirit of the present invention.

For example, although the above-described embodiments have been described by way of an example of the grooved piezoelectric vibrating reed 4 in which the groove portions 18 are formed on both surfaces of the vibrating arms 10 and 11 as an example of the piezoelectric vibrating reed 4, the piezoelectric vibrating reed 4 may be a type of piezoelectric vibrating reed without the groove portions 18. However, since the electric field efficiency between the pair of the excitation electrodes 15 when a predetermined voltage is applied to the pair of excitation electrodes 15 can be increased by forming the groove portions 18, it is possible to suppress the vibration loss further and to improve the vibration properties much more. That is to say, it is possible to decrease the CI value (crystal impedance) further and to improve the performance of the piezoelectric vibrating reed 4 further. In this respect, it is preferable to form the groove portions 18.

Moreover, although in the above-described embodiments, the base board 2 and the lid board 3 are anodically bonded by the bonding film 35, the bonding method is not limited to the anodic bonding. However, the anodic bonding is preferable because the anodic bonding can tightly bond both boards 2 and 3.

Furthermore, although in the above-described embodiments, the piezoelectric vibrating reed 4 is bonded by bumps, the bonding method is not limited to the bump bonding. For example, the piezoelectric vibrating reed 4 may be bonded by a conductive adhesive agent. However, since the bump bonding allows the piezoelectric vibrating reed 4 to be floated from the upper surface of the base board 2, it is naturally possible to secure the minimum vibration gap necessary for vibration of the piezoelectric vibrating reed 4. Therefore, bump bonding is preferable.

Furthermore, although in the above-described embodiments, the gettering material 34 and the bonding film 35 are formed of different materials, they may be formed of the same materials. When the gettering material 34 and the bonding film 35 are formed of different materials, for example, the gettering material 34 and the bonding film 35 may be formed of materials (for example, zirconium for the gettering material 34 and aluminum for the bonding film 35) which are respectively capable of absorbing different surrounding gases by being activated with laser irradiation.

Besides, within a range not deviating from the object of the present invention, constituent elements of the above-described embodiments may be appropriately substituted with well-known constituent elements, and the above-described modified examples may be appropriately combined.

What is claimed is:

1. A piezoelectric vibrator comprising:
a hermetically closed casing comprising first and second substrates with a cavity therebetween, at least one of which is made of a translucent material, at least one of which is layered with a bonding film, having a gettering characteristic, extensive over at least part of a surface thereof facing the other substrate, and which are anodically bonded via the bonding film;
a piezoelectric vibrating strip secured inside the cavity; and
at least one getter material attached to an interior surface of the casing so as to be directly irradiatable with a laser from the outside of the casing via an area of the casing to which the at least one getter material is attached.

2. The piezoelectric vibrator according to claim 1, wherein the at least one getter material has a series of laser irradiation marks, and the bonding film has a corresponding number of laser irradiation marks at corresponding locations, both of which are formed by simultaneous irradiations of laser.

3. The piezoelectric vibrator according to claim 1, wherein the at least one getter material has a series of irradiation marks, and the bonding film has irradiation marks more than a number of irradiation marks of the at least one getter material.

4. The piezoelectric vibrator according to claim 1, wherein the at least one getter material and the bonding film are made of different getter materials.

5. A method for producing piezoelectric vibrators, comprising:
(a) defining a plurality of first substrates on a first wafer and a plurality of second substrates on a second wafer;
(b) layering the first and second wafers such that at least some of the first substrates substantially coincide respectively with at least some of the corresponding second substrates, with a piezoelectric vibrating strip being secured in respective pairs of at least some of coinciding first and second substrates, wherein at least some of the pairs include a getter material inside, and at least some of the pairs include a bonding film, having a gettering characteristic, layered at least in part over a surface of one of the first and second substrates facing the other substrate;
(c) anodically bonding the first and second substrates of at least some of the pairs in step (b) via the bonding film;
(d) irradiating a laser to at least one pair of the bonded first and second substrates from outside thereof to simultaneously heat the getter material and the bonding film thereof to vacuum inside of the at least one pair; and
(e) cutting off each of at least some pairs from the first and second wafers.

6. The method according to claim 5, further comprising after step (d), irradiating a laser to the at least one pair to heat only the bonding film to further vacuum inside of the at least one pair.

7. The method according to claim 5, further comprising after step (d):
supplying electricity to the at least one pair to vibrate the piezoelectric vibrating strip inside and detecting a series resonance resistance of the vibrating piezoelectric vibrating strip; and
if the detected series resonance resistance is not within an acceptable range, performing step (d).

8. The method according to claim 6, further comprising after step (d):
supplying electricity to the at least one pair to vibrate the piezoelectric vibrating strip inside and detecting a series resonance resistance of the vibrating piezoelectric vibrating strip; and
depending on a deviation of the detected series resonance resistance from an acceptable value, performing one of (i) irradiating a laser to simultaneously heat the getter material and the bonding film and (ii) irradiating a laser to heat only the bonding film.

9. An oscillator comprising the piezoelectric vibrator according to claim 1, which is connected to an integrated circuit of the oscillator.

10. An electronic device comprising:
a clock; and
the piezoelectric vibrator according to claim 1 electrically connected to the clock.

11. A radio-controlled clock comprising:
a filter; and
the piezoelectric vibrator according to claim 1 electrically connected to the filter.
